(19) United States
(12) Patent Application Publication
(10) Pub. No.: US 2026/0163537 A1
(43) Pub. Date: Jun. 11, 2026

(54) POWER AMPLIFIER DEVICE, REMOTE RADIO UNIT, AND BASE STATION

(71) Applicant: HUAWEI TECHNOLOGIES CO., LTD., Shenzhen (CN)

(72) Inventors: Jinhu Chen, Chengdu (CN); Hailei Suo, Chengdu (CN); Xueming Yu, Shanghai (CN); Yijun Sun, Shenzhen (CN); Zhixiong Zeng, Shanghai (CN); Jie Sun, Shanghai (CN)

(73) Assignee: HUAWEI TECHNOLOGIES CO., LTD., Shenzhen (CN)

(21) Appl. No.: 19/178,900

(22) Filed: Apr. 15, 2025

Related U.S. Application Data
(63) Continuation of application No. PCT/CN2022/125795, filed on Oct. 18, 2022.

(51) Int. Cl. H03F 3/24; H01P 1/38; H04B 1/04

(52) U.S. Cl. CPC H03F 3/245; H01P 1/38; H04B 1/04; H03F 2200/451; H04B 2001/0408

(57) ABSTRACT

The present disclosure discloses a power amplifier device, a remote radio unit, and a base station. The power amplifier device is applicable to input of up to three signals, and combines power through hybrid cascading of a coupler and a circulator. The coupler may be used as a last-stage power combination unit, or the circulator may be used as a last-stage power combination unit. The power amplifier device may generate at least three high-efficiency points.

### CROSS-REFERENCE TO RELATED APPLICATIONS

This application of International Patent Application No. PCT/CN2022/125795, filed on Oct. 18, 2022, the disclosure of which is hereby incorporated by reference in its entirety.

### TECHNICAL FIELD

The present disclosure relates to the field of communication device technologies, and in particular, to a power amplifier device, a remote radio unit, and a base station.

### BACKGROUND

Currently, a wireless communication system requires a wide bandwidth and high spectral efficiency. For example, a 5G NR (5G New Radio) standard defines an N77 frequency band from 3.3 GHz to 4.2 GHz, that is, a bandwidth of 900 MHz, used for concurrent broadband signals. In addition, a peak-to-average ratio of a high-frequency spectrum signal waveform of the 5G NR is still up to 9 dB even if a crest factor reduction (CFR peak clipping technology is used. A high peak-to-average power ratio (PAPR) and a wide instantaneous bandwidth bring new challenges to a power amplifier (PA) of a base station.

Therefore, with development of the wireless communication system, the power amplifier of the base station needs to satisfy high efficiency while implementing an ultra-wideband feature.

### SUMMARY

To resolve the foregoing technical problems, the present disclosure provides a power amplifier device, a remote radio unit, and a base station, to satisfy high efficiency while implementing an ultra-wideband feature.

The present disclosure provides a power amplifier device. In addition to the following three power amplifier circuits: a first power amplifier circuit, a second power amplifier circuit, and a third power amplifier circuit, the power amplifier device further includes a first coupler and a circulator. The circulator is used as a last-stage power combination unit. Input ends of the first power amplifier circuit, the second power amplifier circuit, and the third power amplifier circuit input a first signal, a second signal, and a third signal respectively. Both an output end of the first power amplifier circuit and an output end of the second power amplifier circuit are connected to an input port of the first coupler, and the first coupler outputs a signal obtained through power combination. An output port of the first coupler and an output end of the third power amplifier circuit are coupled to the circulator, and the circulator combines power of a signal output by the third power amplifier circuit and the signal output by the first coupler, and then outputs a signal obtained through power combination.

The power amplifier device provided in the present disclosure is applicable to input of up to three signals, and combines power through hybrid cascading of the coupler and the circulator. The coupler may be used as a last-stage power combination unit, or the circulator may be used as a last-stage power combination unit. The power amplifier device may generate at least three high-efficiency points. Because there are a plurality of high-efficiency points, a problem of an efficiency pit during large backoff can be alleviated, and modulation wave efficiency of a radio frequency power amplifier device can be improved. In addition, a working bandwidth of the power amplifier device depends on working bandwidths of the first power amplifier circuit, the coupler, and the circulator, so that an ultra-wideband high-power design can be implemented. Moreover, the last-stage power combination unit of the power amplifier is implemented by the circulator. The circulator is more suitable for a scenario of a large power capacity. Therefore, the power amplifier is applicable to a large-power ultra-wideband scenario.

The present disclosure further provides a power amplifier device. In addition to the following three power amplifier circuits: a first power amplifier circuit, a second power amplifier circuit, and a third power amplifier circuit, the power amplifier device further includes a first coupler and a circulator. The coupler is used as a last-stage power combination unit. Input ends of the first power amplifier circuit, the second power amplifier circuit, and the third power amplifier circuit input a first signal, a second signal, and a third signal respectively. Both an output end of the first power amplifier circuit and an output end of the second power amplifier circuit are coupled to the circulator, and the circulator is configured to output a signal obtained through power combination. An output port of the circulator and an output end of the third power amplifier circuit are coupled to the first coupler, and the first coupler is configured to: combine power of a signal output by the third power amplifier circuit and the signal output by the circulator, and then output a signal obtained through power combination.

Characteristic impedance of the circulator is not specifically limited in the present disclosure, for example, may be 50 ohms.

An implementation form of the first power amplifier circuit is not specifically limited in the present disclosure. The first power amplifier circuit may be a single-transistor power amplifier, or may be an integrated power amplifier. For example, the first power amplifier circuit may include any one of the following: a single-transistor power amplifier, a Doherty power amplifier, a Chireix power amplifier, a load modulated balanced amplifier (LMBA), or a circulator load modulated amplifier (CLMA) power amplifier.

The second power amplifier circuit includes a first amplification branch and a second amplification branch, and the third power amplifier circuit includes a third amplification branch. The first amplification branch and the second amplification branch are the same, and are both biased in shallow class C. The third amplification branch is biased in deep class C. For example, the first amplification branch, the second amplification branch, and the third amplification branch may all be peak power amplifiers, which are briefly referred to as Peak.

The following uses an example in which the first power amplifier circuit is a single-transistor power amplifier for description. The single-transistor power amplifier is a carrier power amplifier when biased in class AB or class B, and is briefly referred to as Main. The power amplifier device further includes a second coupler and a matching circuit. An input end of the carrier power amplifier is configured to input the first signal, and an output end of the carrier power amplifier is coupled to an isolation port of the first coupler. A first input port of the second coupler is configured to input the second signal, and a second input port of the second coupler is coupled to a load. The first input port of the second coupler is configured to couple to the second signal, and the second input port of the second coupler is configured to couple to the load. Two output ports of the second coupler are respectively coupled to an input end of the first amplification branch and an input end of the second amplification branch, and an output end of the first amplification branch and an output end of the second amplification branch are respectively coupled to two balanced ports of the first coupler. The output port of the first coupler is coupled to a first end of the matching circuit, and a second end of the matching circuit is coupled to an isolation port of the circulator. An input end of the third amplification branch is configured to input the third signal, an output end of the third amplification branch is coupled to an input port of the circulator, and an output port of the circulator is configured to output a signal obtained by combining power of signals of the isolation port and the input port.

A load-pull ratio of the first power amplifier circuit is 1. In other words, load of the first power amplifier circuit is unchanged with a change in power of the power amplifier device. Therefore, a working bandwidth of the power amplifier device depends only on a working bandwidth of the single-transistor power amplifier and working bandwidths of the coupler and the circulator, and ultra-wideband can be implemented through a design. In addition, the power amplifier has three high-efficiency points, so that a problem of a large pit during power backoff can be alleviated. Moreover, the last-stage power combination unit of the power amplifier is implemented by the circulator. The circulator is more suitable for a scenario of a large power capacity. Therefore, the power amplifier is applicable to a large-power ultra-wideband scenario.

To implement miniaturization of the power amplifier, the coupler may be designed by using an integrated passive device. The circulator may be a three-port design. In addition, the circulator may be designed, together with an isolator coupled to the output port, as a four-port circulator.

The power amplifier device provided in the present disclosure may alternatively input two signals. In addition to the foregoing included components, the power amplifier device further includes a first power division circuit and a first phase compensation network. The first power division circuit is configured to output the first signal and the second signal, one end that is of the first power division circuit and that outputs the first signal is coupled to an input end of the first phase compensation network, an output end of the first phase compensation network is coupled to the input end of the carrier power amplifier, and one end that is of the first power division circuit and that outputs the second signal is coupled to the first input port of the second coupler.

The power amplifier device provided in the present disclosure may alternatively input one signal. In addition to the foregoing included components, the power amplifier device further includes a second power division circuit and a second phase compensation network. Two output ends of the second power division circuit are respectively coupled to an input end of the first power division circuit and an input end of the second phase compensation network. An output end of the second phase compensation network is coupled to the input end of the third amplification branch.

The first power amplifier circuit is a single-transistor power amplifier, and the single-transistor power amplifier is a carrier power amplifier when biased in class AB or class B. The second power amplifier circuit includes a fourth amplification branch, and the third power amplifier circuit includes a fifth amplification branch and a sixth amplification branch. The fourth amplification branch is biased in shallow class C, the fifth amplification branch and the sixth amplification branch are the same, and are both biased in deep class C.

The following describes a specific implementation in which the circulator is used as the last-stage power combination unit. The power amplifier device further includes a second coupler, a first matching circuit, and a second matching circuit. The input end of the first power amplifier circuit is configured to input the first signal, and the output end of the first power amplifier circuit is coupled to an isolation port of the circulator. An input end of the fourth amplification branch is configured to coupled to the second signal, an output end of the fourth amplification branch is coupled to an input port of the circulator, an output port of the circulator is coupled to a first end of the first matching circuit, and a second end of the first matching circuit is coupled to an isolation port of the first coupler. A first input port of the second coupler is configured to input the third signal, and a second input port of the second coupler is coupled to a load. The first input port of the second coupler is configured to couple to the third signal, and the second input port of the second coupler is configured to couple to the load. An input end of the fifth amplification branch and an input end of the sixth amplification branch are respectively coupled to two output ports of the second coupler, and an output end of the fifth amplification branch and an output end of the sixth amplification branch are respectively coupled to two balanced ports of the first coupler. An output port of the first coupler is coupled to a first end of the second matching circuit, and an output end of the second matching circuit is configured to output a signal obtained through power combination.

In the power amplifier device provided in the present disclosure, the first power amplifier circuit works first, the second power amplifier circuit works later, and the third power amplifier circuit works last. The first power amplifier circuit reaches saturation first, then the second power amplifier circuit reaches saturation, and finally the third power amplifier circuit reaches saturation.

Based on the power amplifier device provided above, the present disclosure further provides a remote radio unit, including the power amplifier device described above, and further including a duplexer. One end of the power amplifier device is coupled to the duplexer, and the duplexer can send and receive a radio frequency signal.

Based on the remote radio unit provided above, the present disclosure further provides a base station, including the remote radio unit described above, and further including an antenna. The remote radio unit is coupled to the antenna, and the remote radio unit is configured to process a transmitted/received signal of the antenna.

### BRIEF DESCRIPTION OF DRAWINGS

FIG. 1 is a schematic of a remote radio unit RRU.

FIG. 2 is a schematic of a power amplifier device according to an embodiment of the present disclosure.

FIG. 3 is a diagram of a current of a power amplifier device according to an embodiment of the present disclosure.

FIG. 4 is a diagram of a voltage of a power amplifier device according to an embodiment of the present disclosure.

FIG. 5 is a diagram of impedance of a power amplifier device according to an embodiment of the present disclosure.

FIG. 6 is a diagram of an efficiency curve corresponding to FIG. 2 according to an embodiment of the present disclosure.

FIG. 7 is a schematic of a power amplifier corresponding to two signals according to an embodiment of the present disclosure.

FIG. 8 is a schematic of a power amplifier corresponding to one signal according to an embodiment of the present disclosure.

FIG. 9 is a diagram of an efficiency curve according to an embodiment of the present disclosure.

FIG. 10 is a schematic of another power amplifier device according to an embodiment of the present disclosure.

FIG. 11 is a diagram of an efficiency curve corresponding to FIG. 10.

FIG. 12 is a schematic of still another power amplifier device according to an embodiment of the present disclosure.

FIG. 13 is a diagram of an efficiency curve corresponding to FIG. 12.

FIG. 14 is a schematic of a base station according to an embodiment of the present disclosure.

### DESCRIPTION OF EMBODIMENTS

The following describes technical solutions in embodiments of the present disclosure with reference to accompanying drawings in embodiments of the present disclosure.

In the following descriptions, terms such as “first” and “second” are merely intended for a purpose of description, and shall not be understood as an indication or implication of relative importance or an implicit indication of a quantity of indicated technical features. Therefore, a feature limited by “first”, “second”, or the like may explicitly or implicitly include one or more features. In the descriptions of the present disclosure, unless otherwise stated, “a plurality of” means two or more than two.

In the present disclosure, unless otherwise clearly specified and limited, a term “connection” should be understood in a broad sense. For example, the “connection” may be a fixed connection, a detachable connection, or an integrated connection, or may be a direct connection or an indirect connection implemented through an intermediate medium. In addition, a term “coupling” may be a manner of implementing an electrical connection for signal transmission. The “coupling” may be a direct electrical connection, or may be an indirect electrical connection through an intermediate medium.

To implement ultra-wideband high-efficiency power amplification on an input signal, the present disclosure provides a power amplifier device, which is applicable to input of up to three signals, and combines power through hybrid cascading of a coupler and a circulator, so that three high-efficiency points can be generated, and a problem of an efficiency pit during large backoff can be resolved. The efficiency pit is a trough on an efficiency curve during power backoff. The power amplifier device is applicable to a high-power power amplifier scenario.

To make a person skilled in the art better understand the technical solutions provided in embodiments of the present disclosure, the following first describes an application scenario of the technical solutions with reference to the accompanying drawings.

An example in which the power amplifier device provided in embodiments of the present disclosure is used in a remote radio unit (RRU) in a base station is used for description.

The RRU generally includes a plurality of radio frequency modules, and a power amplifier device is an important part of the RRU. A radio signal is amplified by a power amplifier and then is transmitted through an antenna. Because a signal processed by the power amplifier device is a radio frequency signal, the power amplifier device is a radio frequency power amplifier device. Embodiments of the present disclosure specifically relate to the power amplifier device inside the RRU. The power amplifier device includes a power amplifier. For ease of description, the power amplifier is briefly referred to as a power amplifier in the following.

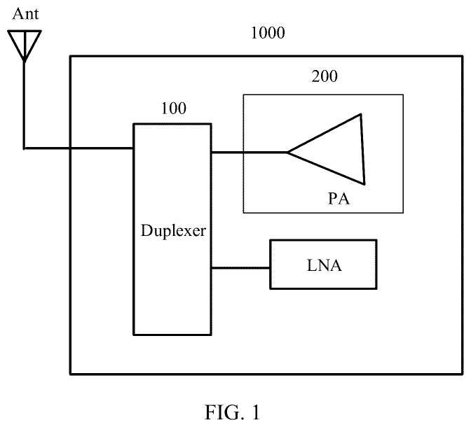

FIG. 1 is a schematic of an RRU.

The RRU 1000 provided in this embodiment of the present disclosure may be used in a wireless communication base station. In addition to the RRU 1000, the base station may further include another component, for example, may further include an antenna Ant. Details are not described herein again.

The RRU 1000 includes a power amplifier device 200, a low noise amplifier (LNA), and a duplexer 100. The power amplifier device 200 includes a power amplifier PA.

A radio frequency signal amplified by the PA is sent to the antenna Ant through the duplexer 100.

The radio frequency signal received by the antenna Ant is sent to the LNA through the duplexer 100.

According to the power amplifier device 200 provided in this embodiment of the present disclosure, a final power combination unit in the power amplifier device may be a coupler or a circulator. The following provides detailed descriptions with reference to the accompanying drawings. First, an implementation in which a final signal is output by the circulator is described.

The power amplifier device provided in this embodiment includes: a first power amplifier circuit, a second power amplifier circuit, a third power amplifier circuit, a coupler, and a circulator. A first signal and a second signal are respectively amplified by the first power amplifier circuit and the second power amplifier circuit and then input to the coupler, and the coupler combines power to obtain a signal for output. A third signal is amplified by the third power amplifier circuit and then output, and the circulator combines power of a signal output by the third power amplifier circuit and the signal output by the coupler and then outputs a signal obtained through power combination.

The first power amplifier circuit works first, the second power amplifier circuit works later, and the third power amplifier circuit works last.

The first power amplifier circuit may be implemented in a plurality of forms. For example, the first power amplifier circuit may include any one of the following: a single-transistor power amplifier, a Doherty power amplifier, a Chireix power amplifier, an LMBA, or a CLMA.

When the first power amplifier circuit is implemented by the single-transistor power amplifier, the single-transistor power amplifier is biased in class AB or class B, may be referred to as a carrier power amplifier, is also referred to as a main power amplifier, and is represented by Main. The following describes implementation in which the first power amplifier circuit is implemented by the single-transistor power amplifier.

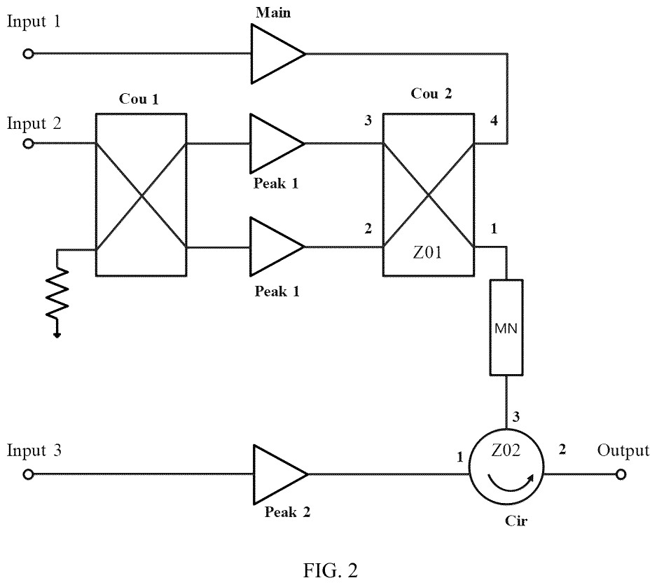

FIG. 2 is a schematic of a power amplifier device according to an embodiment of the present disclosure.

The first power amplifier circuit is a single-transistor power amplifier, and is referred to as a carrier power amplifier Main. The carrier power amplifier is also referred to as a main power amplifier.

The second power amplifier circuit includes a first amplification branch and a second amplification branch. The first amplification branch and the second amplification branch are the same, are both biased in shallow class C, and are therefore both represented by Peak 1. It should be understood that the amplification branch provided in this embodiment of the present disclosure may include a peak power amplifier, and the peak power amplifier is also referred to as an auxiliary power amplifier.

The third power amplifier circuit includes a third amplification branch, and the third amplification branch is biased in deep class C, and is represented by Peak 2.

As shown in FIG. 2, a first signal Input 1 is input to an input end of the carrier power amplifier Main, and an output end of the carrier power amplifier Main is coupled to an isolation port of a first coupler Cou 2.

A second signal Input 2 is input to a first input port of the second coupler Cou 1, and a second input port of the second coupler Cou 1 is coupled to a load. Power division is performed on the second signal Input 2 by the second coupler Cou 1, and then divided signals are input to an input end of the first amplification branch Peak 1 and an input end of the second amplification branch Peak 1 respectively. An output end of the first amplification branch Peak 1 and an output end of the second amplification branch Peak 1 are respectively coupled to two balanced ports of the first coupler Cou 2.

An output port of the first coupler Cou 2 is coupled to an isolation port 3 of a circulator Cir through a matching circuit MN.

A third signal Input 3 is input to an input end of the third amplification branch Peak 2, an output end of the third amplification branch Peak 2 is coupled to an input port 1 of the circulator Cir, and an output port 2 of the circulator Cir is configured to output a signal obtained by combining power of signals of the isolation port of the circulator and the input port of the circulator, that is, output a final amplified signal at Output.

Characteristic impedance of the first coupler Cou 2 is Z01. Characteristic impedance of the circulator Cir is Z02. It should be noted that the characteristic impedance Z02 of the circulator is generally 50 ohms.

A function of a matching circuit MN is to implement conversion between the impedance Z01 and the impedance Z02, to implement impedance matching between the first coupler Cou 2 and the circulator Cir.

When power of an input signal is low, because Main works in class AB or class B, Main works first, that is, only Main works. After Main reaches saturation, the two Peaks 1 are coupled and work. At this time, Peak 2 is still in a disconnected state, and Main remains in a saturated state until the two Peaks 1 reach a saturated state. After Peaks 1 reach saturation, Peak 2 is coupled and work. Main and Peaks 1 remain in the saturated state until Main, the two Peaks 1, and Peak 2 all reach saturation.

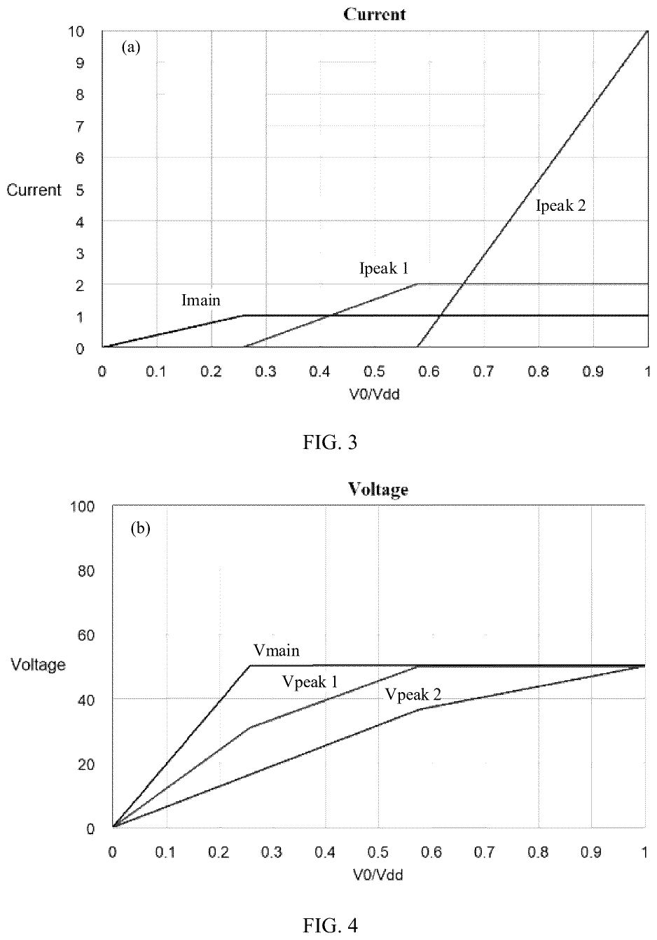

For example, when voltages are normalized at Main:Peak 1:Peak 1:Peak 2=1:2:2:10, for a schematic of currents and a schematic of voltages of Main, the two Peaks 1, and Peak 2, refer to FIG. 3 and FIG. 4 respectively.

Horizontal coordinates in FIG. 3 and FIG. 4 are both a normalized voltage (V0/Vdd), a vertical coordinate in FIG. 3 represents a current, and a vertical coordinate in FIG. 4 represents a voltage.

It can be learned from the current diagram shown in FIG. 3 that Main works first, then Peaks 1 work, and Peak 2 works last. In FIG. 3, Imain reaches current saturation earlier than Ipeak 1, and Ipeak 1 reaches current saturation earlier than Ipeak 2.

It can be learned from the voltage diagram shown in FIG. 4 that Main is saturated first, then Peaks 1 are saturated, and finally Peak 2 is saturated. In other words, in FIG. 3, Vmain reaches voltage saturation earlier than Vpeak 1, Vpeak 1 reaches voltage saturation earlier than Vpeak 2, and Vpeak 2 reaches voltage saturation last.

There is no load pull between Main and Peak 1, and there is no load pull between both Main and Peak 1 and Peak 2. A load-pull ratio of Main is 1. Therefore, a working bandwidth of the power amplifier device shown in FIG. 2 depends only on a working bandwidth of the single-transistor power amplifier and working bandwidths of the coupler and the circulator.

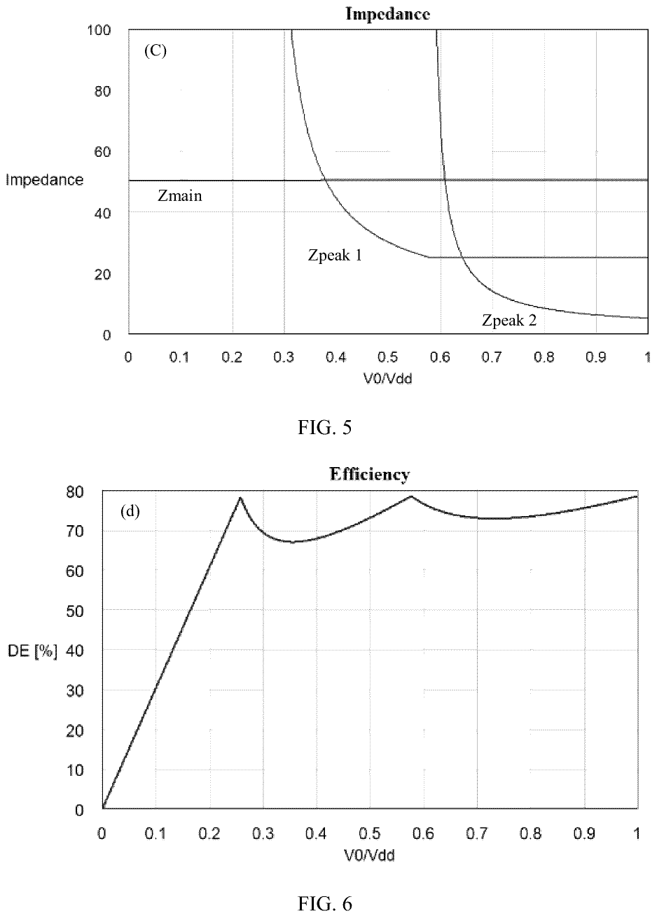

FIG. 5 is a diagram of an impedance relationship between Main, the two Peaks 1, and Peak 2 in a case in which voltages are normalized at Main:Peak 1:Peak 1:Peak 2=1:2:2:10.

A horizontal coordinate in FIG. 5 is a normalized voltage (V0/Vdd), and a vertical coordinate in FIG. 5 represents impedance.

It can be learned from FIG. 5 that impedance Zmain of Main remains unchanged, that is, is a straight line parallel to a horizontal axis. Therefore, the load-pull ratio of Main is 1.

The power amplifier device provided in this embodiment of the present disclosure can achieve three high-efficiency points. The following provides detailed descriptions with reference to an efficiency curve.

FIG. 6 is a diagram of an efficiency curve corresponding to FIG. 2 according to an embodiment of the present disclosure.

The case in which the voltages are normalized at Main:Peak 1:Peak 1:Peak 2=1:2:2:10 is still used for description in FIG. 6. A horizontal coordinate in FIG. 6 is a normalized voltage (V0/Vdd), and a vertical coordinate in FIG. 6 represents efficiency (DE).

Main reaches saturation at a first high-efficiency point. Peaks 1 reach saturation at a second high-efficiency point. Main, Peaks 1, and Peak 2 all reach in a saturated state at a third high-efficiency point. Therefore, the power amplifier provided in this embodiment of the present disclosure may generate three high-efficiency points.

The power amplifier device provided in this embodiment of the present disclosure is in an LMBA working state between the first high-efficiency point and the second high-efficiency point, and is in a CLMA working state between the second high-efficiency point and the third high-efficiency point.

In the power amplifier device provided in this embodiment, because the load-pull ratio of Main is 1, a bandwidth of the power amplifier is related to Main, the coupler, and the circulator, and ultra-wideband can be implemented through a design. In addition, the power amplifier device has three high-efficiency points, so that a problem of a large pit during power backoff can be alleviated. Moreover, a last-stage power combination unit of the power amplifier device is implemented by the circulator. The circulator is more suitable for a scenario of a large power capacity. Therefore, the power amplifier device is applicable to a large-power ultra-wideband scenario.

The characteristic impedance of the foregoing coupler and circulator may be set according to an actual requirement. For example, when the impedance of the circulator is not 50 ohms, to achieve effect of 50 ohms, an impedance conversion network in which Z02 is 50 ohms may be added at the output end Output as required.

In addition, to implement miniaturization of the power amplifier, the coupler may be designed by using an integrated passive device (IPD).

The circulator shown in FIG. 2 is a three-port design.

The circulator may be designed, together with an isolator coupled to Output, as a four-port circulator.

The power amplifier device is described in FIG. 2 by using an example in which three signals are input to the power amplifier. It should be understood that the power amplifier device provided in this embodiment of the present disclosure may also be used in a scenario in which one signal is input or two signals are input. The following provides detailed descriptions with reference to the accompanying drawings.

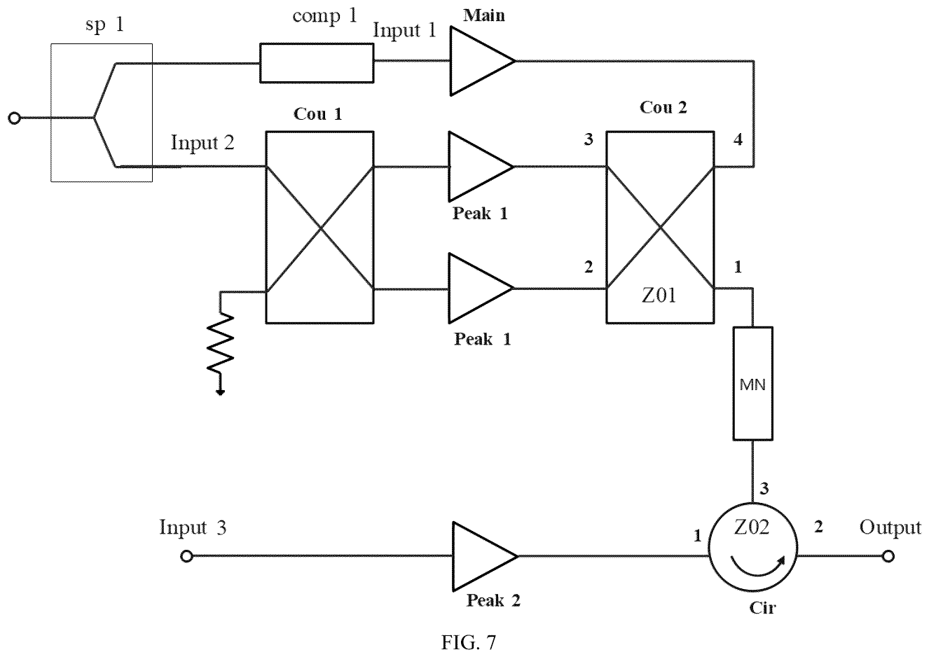

FIG. 7 is a schematic of a power amplifier device corresponding to two signals according to an embodiment of the present disclosure.

An input end of the power amplifier device provided in this embodiment may be coupled to two signals. It can be learned by comparing FIG. 2 with FIG. 7 that, in addition to the components in FIG. 2, FIG. 7 further includes a first power division circuit Sp 1 and a first phase compensation network Comp 1.

The first signal and the second signal in FIG. 2 may be considered as two signals obtained through power division by the first power division circuit Sp 1, and the first signal is coupled to an input end of a carrier power amplifier Main through the first phase compensation network Comp 1.

A function of the first phase compensation network Comp 1 is to implement phase compensation.

It can be learned that, to amplify power of two input signals, in the power amplifier device provided in this embodiment of the present disclosure, the first power division circuit Sp 1 and the first phase compensation network Comp 1 are added on a basis of FIG. 2.

In addition, the power amplifier device provided in this embodiment of the present disclosure may be further used in a scenario in which a single signal is input. A second power division circuit and a second phase compensation network are further added on a basis of FIG. 7, so that power of a single input signal can be amplified.

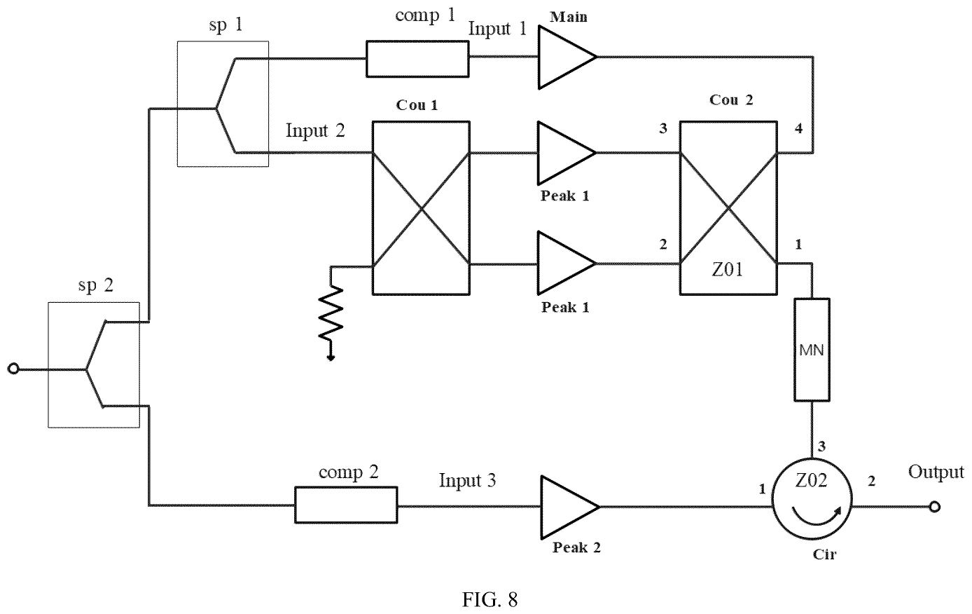

FIG. 8 is a schematic of a power amplifier device corresponding to one signal according to an embodiment of the present disclosure.

It can be learned by comparing FIG. 7 with FIG. 8 that, in addition to the components in FIG. 7, the power amplifier device in FIG. 8 further includes a second power division circuit Sp 2 and a second phase compensation network Comp 2.

A third signal is coupled to an input end of a third amplification branch Peak 2 through the second phase compensation network Comp 2.

The third signal and an input signal of a first power division circuit Sp 1 are two signals obtained through power division by the second power division circuit Sp 2.

To fully understand high efficiency and a backoff amount of the power amplifier device provided in embodiments of the present disclosure, the following provides detailed descriptions with reference to the accompanying drawings.

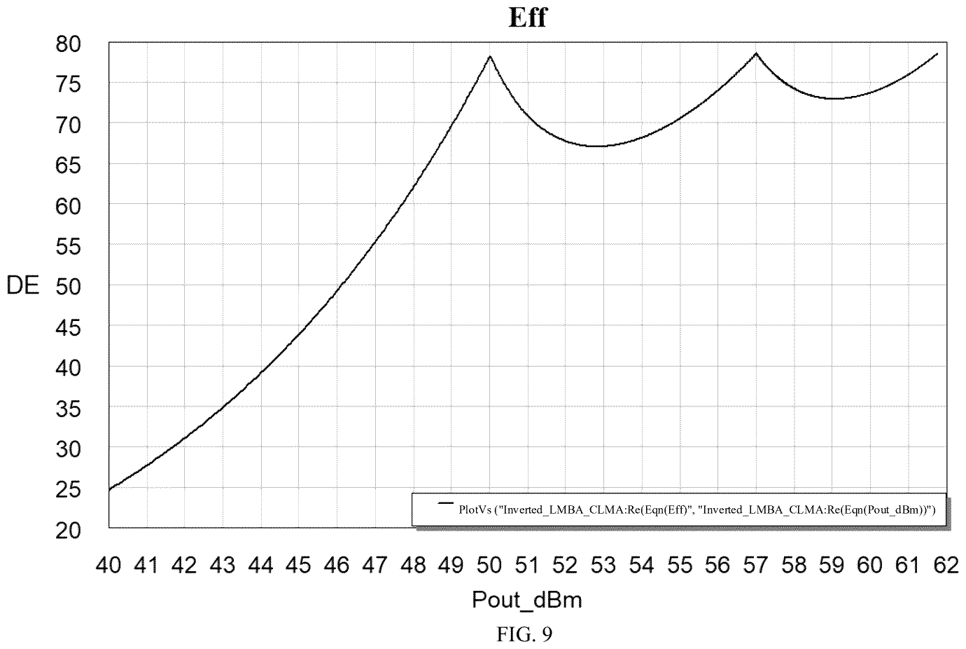

FIG. 9 is a diagram of an efficiency curve according to an embodiment of the present disclosure.

FIG. 9 shows efficiency Eff of a power amplifier device. In FIG. 9, a horizontal coordinate is output power of the power amplifier device, and a vertical coordinate is efficiency DE.

For example, three high-efficiency points of the power amplifier device provided in this embodiment appear at three power points respectively: full power 0 dB, a first power backoff point BO 1, and a second power backoff point BO 2. BO 1 and BO 2 are calculated as follows:

$$BO 2 = 10 \cdot {log}_{10}^{( {Psat}_{main} / ( {Psat}_{main} + 2 * {Psat}_{peak 1} + Psat \_ peak 2 ) )}$$

$$BO 1 = 10 \cdot {log}_{10}^{( ( {Psat}_{main} + 2 * {Psat}_{peak 1} ) / ( {Psat}_{main} + 2 * {Psat}_{peak 1} + Psat \_ peak 2 ) )}$$

Psatₘₐᵢₙ represents saturation power of Main, Psatₚₑₐₖ₁ represents saturation power of Peak 1, and Psatₚₑₐₖ₂ represents saturation power of Peak 2.

It is assumed that Main:Peak 1:Peak 1:Peak 2=100 W:200 W:200 W:1000 W. In this case, BO 1=11.76, and BO 2=4.77 dB. The efficiency curve is shown in FIG. 9. The three high-efficiency points are generated at 61.77 dBm, 57 dBm, and 50 dBm respectively. To be specific, a position of a curve peak is the high-efficiency point, and a power backoff amount may reach 11.76 dB. In other words, the power backoff amount is large, and a pit is small.

The first power amplifier circuit in the power amplifier device described in the foregoing embodiment is implemented by the single-transistor power amplifier. The following describes implementation in which the first power amplifier circuit is implemented by a Doherty power amplifier. It should be understood that, in addition to the Doherty power amplifier, the first power amplifier circuit may also be implemented by a Chireix power amplifier, an LMBA power amplifier, or a CLMA power amplifier.

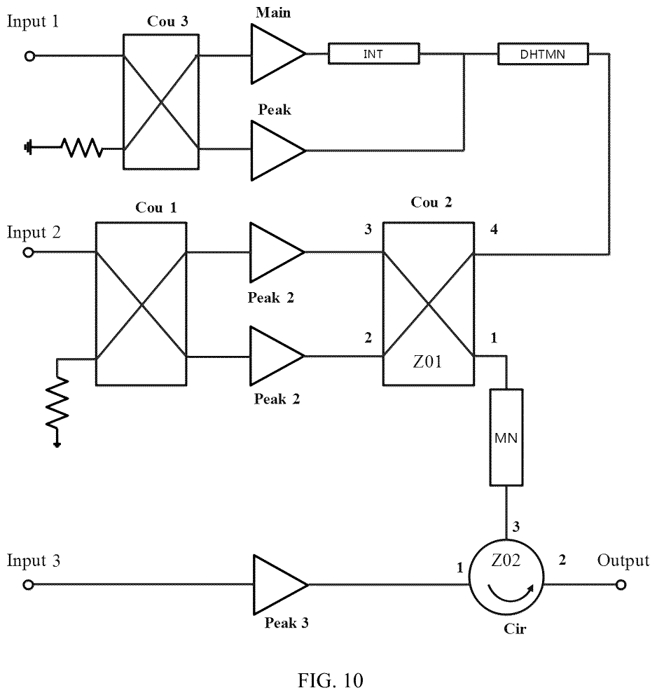

FIG. 10 is a schematic of another power amplifier device according to an embodiment of the present disclosure.

It can be learned by comparing FIG. 2 with FIG. 10 that Main in FIG. 2 is replaced by the Doherty (DHT for short) power amplifier, and other structures remain unchanged. Details are not described herein again.

The Doherty power amplifier includes a second coupler Cou 3, a carrier power amplifier Main, and a peak power amplifier Peak, and further includes an impedance inversion network INT and a matching network DHT MN.

A first signal Input 1 is input to a first input port of the second coupler Cou 3, and a second input port of the second coupler Cou 3 is coupled to a load. Power division is performed on the first signal by the second coupler Cou 3, and then divided signals are input to Main and Peak respectively. A signal output by Main is combined, after passing through INT, with a signal output by Peak, and then is input to an isolation port 4 of a first coupler Cou 2 through DHTMN.

In FIG. 10, Main works first, then Peak works, then two Peaks 1 work, and Peak 2 works last. In this embodiment, the Doherty power amplifier is used to replace Main in FIG. 2, so that a design of a power amplifier architecture with ultra-large backoff. A backoff amount of the DHT power amplifier is increased in comparison with a backoff amount in FIG. 2. That is, a backoff amount is further increased.

Compared with the power amplifier device shown in FIG. 2, the power amplifier device shown in FIG. 10 may generate a plurality of high-efficiency points. In FIG. 2, three high-efficiency points may be generated. In FIG. 10, four high-efficiency points may be generated, so that a problem of a large pit during power backoff is further prevented.

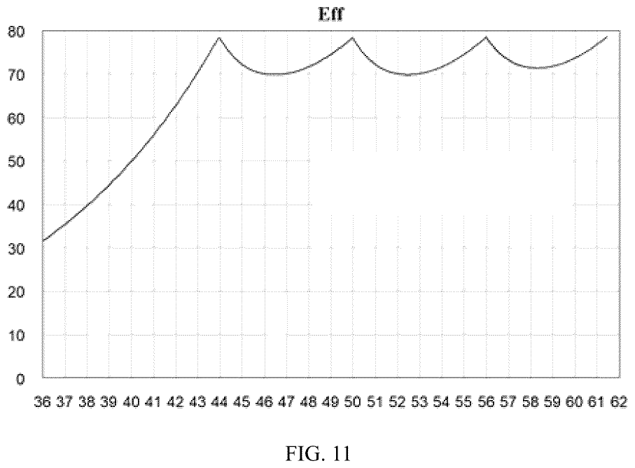

FIG. 11 is a diagram of an efficiency curve corresponding to FIG. 10.

In FIG. 11, a horizontal coordinate is output power Pout in a unit of dBm, and a vertical coordinate is efficiency DE.

For example, Main:Peak:Peak 2:Peak 2:Peak 3=50 W:50 W:200 W:200 W:1000 W, the four high-efficiency points are generated at 61.77 dBm, 57 dBm, 50 dBm, and 44 dBm respectively, and backoff of 17.77 dB is implemented.

When output power is 44 dBm to 50 dBm, pulling is performed by DHT. When output power is 50 dBm to 57 dBm, pulling is performed by LMBA. When output power is 57 dBm to 61.77 dBm, pulling is performed by CLMA.

It should be understood that the power amplifier circuit coupled to the isolation port of the first coupler Cou 2 may be independently disposed, and may be a single-transistor power amplifier, DHT, an asymmetric DHT, a three-way DHT, a four-way DHT, a Chireix power amplifier, an LMBA power amplifier, or a CLMA power amplifier. A corresponding wideband feature is further determined by a wideband feature of the independently disposed power amplifier circuit.

In the power amplifier devices described in the foregoing embodiments, final output signals are all combined by the circulator. The circulator is more suitable to be a final power combination component for a large-power scenario, and can resolve a power capacity problem of a large-power wideband power amplifier.

The following describes an implementation in which a final output signal is combined by a coupler.

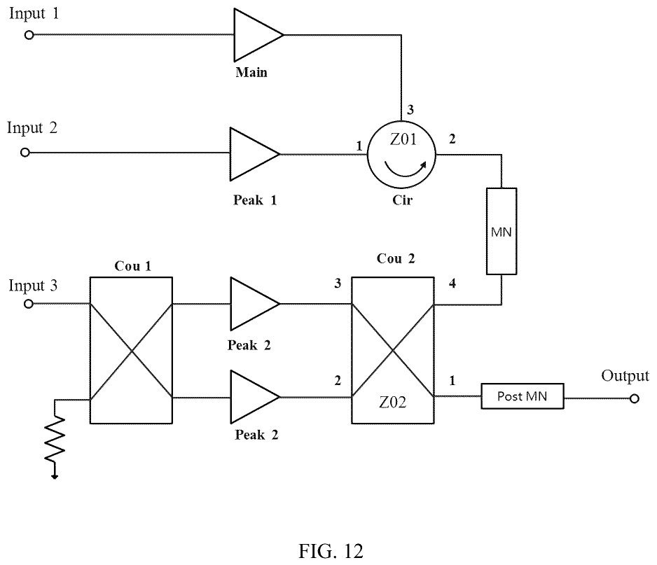

FIG. 12 is a schematic of still another power amplifier device according to an embodiment of the present disclosure.

According to the power amplifier device provided in this embodiment of the present disclosure, a circulator first combines two amplified signals, and then a coupler combines an output signal of the circulator and a third amplified signal, to finally output a signal obtained through power combination.

According to the power amplifier device provided in this embodiment of the present disclosure, a first power amplifier circuit is a single-transistor power amplifier, and the single-transistor power amplifier is biased in class AB or class B, and is referred to as a carrier power amplifier, that is, Main. A second power amplifier circuit includes a fourth amplification branch. A third power amplifier circuit includes a fifth amplification branch and a sixth amplification branch.

The fourth amplification branch is biased in shallow class C, and is represented by Peak 1. The fifth amplification branch and the sixth amplification branch are the same, and are both biased in deep class C, and therefore are represented by Peak 2.

A first signal Input 1 is input to an input end of the first power amplifier circuit Main, and an output end of the first power amplifier circuit Main is coupled to an isolation port of a circulator Cir.

A second signal Input 2 is input to an input end of the fourth amplification branch Peak 1, an output end of the fourth amplification branch Peak 1 is coupled to an input port of the circulator Cir, and an output port of the circulator Cir is coupled to an isolation port of a first coupler Cou 2 through a matching circuit MN.

Impedance of the circulator Cir is Z01, and impedance of the first coupler Cou 2 is Z02. The matching circuit MN implements impedance conversion between Z01 and Z02, to implement impedance matching between the circulator Cir and the first coupler Cou 2.

A third signal Input 3 is input to a first input port of a second coupler Cou 1, and a second input port of the second coupler Cou 1 is coupled to a load. Power division is performed on the third signal Input 3 by the second coupler Cou 1, and then divided signals are input to an input end of the fifth amplification branch Peak 2 and an input end of the sixth amplification branch Peak 2 respectively. An output end of the fifth amplification branch Peak 2 and an output end of the sixth amplification branch Peak 2 are respectively coupled to two balanced ports of the first coupler Cou 2.

An output port of the first coupler Cou 2 outputs, through a matching circuit Post MN, the signal obtained through power combination.

The output port of the first coupler Cou 2 implements impedance conversion from Z02 to 50 ohms through the matching circuit Post MN.

When power is low, only Main works. Peak 1 does not work until Main is saturated. Main remains in a saturated state, and Peaks 2 do not work until Main and Peak 1 both reach saturation. Main and Peak 1 remain in the saturated state until Main, Peak 1, and Peaks 2 all reach saturation. Therefore, load modulation ratio of Main is 1. The power amplifier device provided in this embodiment may generate three high-efficiency points. The following provides detailed descriptions with reference to the diagram of the efficiency curve.

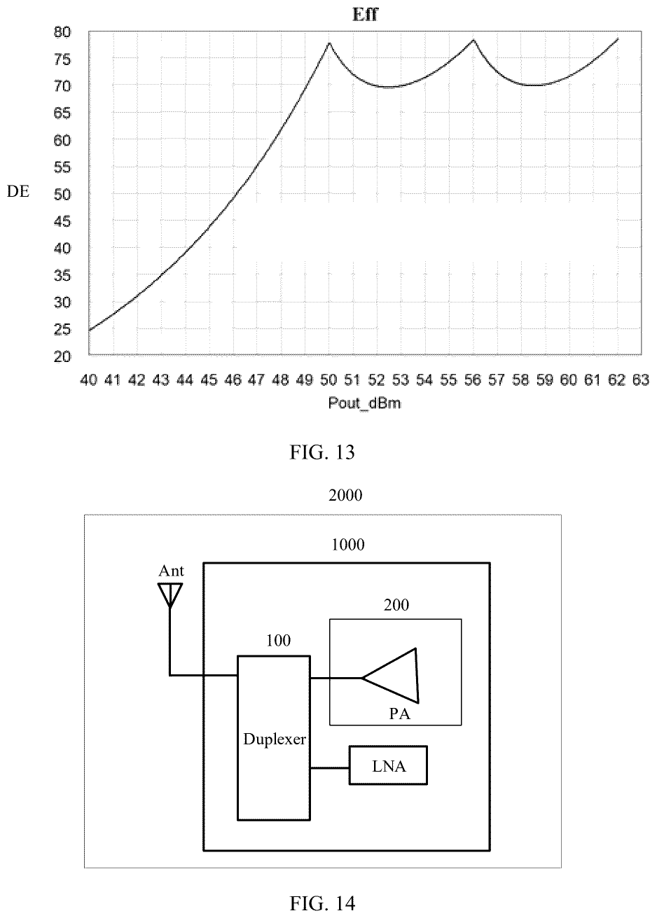

FIG. 13 is a diagram of an efficiency curve corresponding to FIG. 12.

For example, Main:Peak 1:Peak 2:Peak 2=100 W:300 W:600 W:600 W. As shown in FIG. 13, three high-efficiency points are generated at 62 dBm, 56 dBm, and 50 dBm respectively, and large backoff of 12 dB is implemented.

Similarly, in FIG. 12, in addition to the single-transistor power amplifier, the first power amplifier circuit may also be implemented by a DHT power amplifier, a Chireix power amplifier, an LMBA power amplifier, a CLMA power amplifier, or the like. A wideband feature further depends on a wideband feature of a power amplifier coupled to the isolation port 3 of the circulator Cir.

Based on the power amplifier device provided in the foregoing embodiments, an embodiment of the present disclosure further provides a remote radio unit. For details, refer to FIG. 1. FIG. 1 is a schematic of a remote radio unit according to an embodiment of the present disclosure.

The remote radio unit provided in this embodiment includes the power amplifier device described in the foregoing embodiments, and further includes the duplexer 100.

One end of the power amplifier PA is coupled to the duplexer 100. Specifically, the duplexer 100 is coupled between the antenna Ant and the power amplifier PA of the base station, and the duplexer 100 is coupled between the antenna Ant and the low noise amplifier LNA.

In addition, still refer to FIG. 1. The remote radio unit 1000 may further include the LNA, an ADC, and a DAC.

The remote radio unit provided in this embodiment of the present disclosure includes the power amplifier device described in the foregoing embodiments, which is applicable to input of up to three signals, and combines power through hybrid cascading of a coupler and a circulator. The coupler may be used as a last-stage power combination unit, or the circulator may be used as a last-stage power combination unit. The power amplifier device may generate at least three high-efficiency points. Because there are a plurality of high-efficiency points, a problem of an efficiency pit during large backoff can be alleviated. In addition, a working bandwidth of the power amplifier device depends on working bandwidths of a first power amplifier circuit, the coupler, and the circulator, so that ultra-wideband high-power signal processing can be implemented.

Based on the power amplifier device and the remote radio unit that are provided in the foregoing embodiments, an embodiment of the present disclosure further provides a base station. The following provides detailed descriptions with reference to the accompanying drawings.

FIG. 14 is a schematic of a base station according to an embodiment of the present disclosure. An embodiment of the present disclosure further provides a base station 2000, including the remote radio unit 1000 described in the foregoing embodiment, and further including an antenna Ant.

The remote radio unit 1000 is coupled to the antenna Ant.

The remote radio unit 1000 is configured to process a transmitted/received signal of the antenna Ant.

The base station provided in this embodiment of the present disclosure includes the power amplifier device 200 described in the foregoing embodiments, so that a plurality of high-efficiency points can be implemented, and a large pit during backoff can be alleviated. In addition, the base station is applicable to a high-power scenario, and can implement ultra-wideband high-power signal processing.

It should be understood that in the present disclosure, “at least one (item)” means one or more, and “a plurality of” means two or more. Therefore, any simple amendment or equivalent variation and modification made to the foregoing embodiments according to the technical essence of the present disclosure without departing from the content of the technical solutions of the present disclosure shall fall within the protection scope of the technical solutions of the present disclosure.

1. A power amplifier device, comprising:
a first power amplifier circuit;
a second power amplifier circuit;
a third power amplifier circuit;
a first coupler; and
a circulator,
wherein an input end of the first power amplifier circuit is configured to couple to a first signal, an input end of the second power amplifier circuit is configured to couple to a second signal, both an output end of the first power amplifier circuit and an output end of the second power amplifier circuit are coupled to an input port of the first coupler, and the first coupler is configured to output a signal obtained through power combination, and
wherein an input end of the third power amplifier circuit is configured to couple to a third signal, an output port of the first coupler and an output end of the third power amplifier circuit are coupled to the circulator, and the circulator is configured to: combine power of a signal output by the third power amplifier circuit and the signal output by the first coupler, and then output a signal obtained through power combination.

2. The power amplifier device according to claim 1, wherein the second power amplifier circuit comprises a first amplification branch and a second amplification branch, and the third power amplifier circuit comprises a third amplification branch,
wherein the first amplification branch and the second amplification branch are identical, and are both biased in shallow class C, and
wherein the third amplification branch is biased in deep class C.

3. The power amplifier device according to claim 2, wherein the first power amplifier circuit is a single-transistor power amplifier, and the single-transistor power amplifier is a carrier power amplifier when biased in class AB or class B, and the power amplifier device further comprises a second coupler and a matching circuit,
wherein an input end of the carrier power amplifier is configured to input the first signal, and an output end of the carrier power amplifier is coupled to an isolation port of the first coupler,
wherein a first input port of the second coupler is configured to input the second signal, and a second input port of the second coupler is coupled to a load, two output ports of the second coupler are respectively coupled to an input end of the first amplification branch and an input end of the second amplification branch, and an output end of the first amplification branch and an output end of the second amplification branch are respectively coupled to two balanced ports of the first coupler,
wherein the output port of the first coupler is coupled to a first end of the matching circuit, and a second end of the matching circuit is coupled to an isolation port of the circulator, and
wherein an input end of the third amplification branch is configured to input the third signal, an output end of the third amplification branch is coupled to an input port of the circulator, and an output port of the circulator is configured to output a signal obtained by combining power of signals of the isolation port and the input port.

4. The power amplifier device according to claim 2, wherein a load-pull ratio of the first power amplifier circuit is 1.

5. The power amplifier device according to claim 2, further comprising: a first power division circuit and a first phase compensation network, wherein
the first power division circuit is configured to output the first signal and the second signal, one end that is of the first power division circuit and that outputs the first signal is coupled to an input end of the first phase compensation network, an output end of the first phase compensation network is coupled to the input end of the carrier power amplifier, and one end that is of the first power division circuit and that outputs the second signal is coupled to the first input port of the second coupler.

6. The power amplifier device according to claim 5, further comprising: a second power division circuit and a second phase compensation network, wherein
two output ends of the second power division circuit are respectively coupled to an input end of the first power division circuit and an input end of the second phase compensation network, and
an output end of the second phase compensation network is coupled to the input end of the third amplification branch.

7. The power amplifier device according to claim 1, wherein the first power amplifier circuit comprises any one of the following: a Doherty power amplifier, a Chireix power amplifier, a load modulated balanced amplifier (LMBA) power amplifier, or a circulator load modulated amplifier (CLMA) power amplifier.

8. The power amplifier device according to claim 1, wherein the first power amplifier circuit works first, the second power amplifier circuit works later, and the third power amplifier circuit works last.

9. A remote radio unit, comprising:
a power amplifier device; and
a duplexer, wherein one end of the power amplifier device is coupled to the duplexer,
wherein the power amplifier device comprises a first power amplifier circuit, a second power amplifier circuit, a third power amplifier circuit, a first coupler, and a circulator,
wherein an input end of the first power amplifier circuit is configured to couple to a first signal, an input end of the second power amplifier circuit is configured to couple to a second signal, both an output end of the first power amplifier circuit and an output end of the second power amplifier circuit are coupled to an input port of the first coupler, and the first coupler is configured to output a signal obtained through power combination, and
wherein an input end of the third power amplifier circuit is configured to couple to a third signal, an output port of the first coupler and an output end of the third power amplifier circuit are coupled to the circulator, and the circulator is configured to: combine power of a signal output by the third power amplifier circuit and the signal output by the first coupler, and then output a signal obtained through power combination.

10. The remote radio unit according to claim 9, wherein the second power amplifier circuit comprises a first amplification branch and a second amplification branch, and the third power amplifier circuit comprises a third amplification branch,
wherein the first amplification branch and the second amplification branch are identical, and are both biased in shallow class C, and
wherein the third amplification branch is biased in deep class C.

11. The remote radio unit according to claim 10, wherein the first power amplifier circuit is a single-transistor power amplifier, and the single-transistor power amplifier is a carrier power amplifier when biased in class AB or class B, and the power amplifier device further comprises a second coupler and a matching circuit,
wherein an input end of the carrier power amplifier is configured to input the first signal, and an output end of the carrier power amplifier is coupled to an isolation port of the first coupler,
wherein a first input port of the second coupler is configured to input the second signal, and a second input port of the second coupler is coupled to a load; and two output ports of the second coupler are respectively coupled to an input end of the first amplification branch and an input end of the second amplification branch, and an output end of the first amplification branch and an output end of the second amplification branch are respectively coupled to two balanced ports of the first coupler
wherein the output port of the first coupler is coupled to a first end of the matching circuit, and a second end of the matching circuit is coupled to an isolation port of the circulator, and
wherein an input end of the third amplification branch is configured to input the third signal, an output end of the third amplification branch is coupled to an input port of the circulator, and an output port of the circulator is configured to output a signal obtained by combining power of signals of the isolation port and the input port.

12. The remote radio unit according to claim 10, wherein a load-pull ratio of the first power amplifier circuit is 1.

13. The remote radio unit according to claim 10, further comprising: a first power division circuit and a first phase compensation network, wherein
the first power division circuit is configured to output the first signal and the second signal, one end that is of the first power division circuit and that outputs the first signal is coupled to an input end of the first phase compensation network, an output end of the first phase compensation network is coupled to the input end of the carrier power amplifier, and one end that is of the first power division circuit and that outputs the second signal is coupled to the first input port of the second coupler.

14. The remote radio unit according to claim 13, further comprising: a second power division circuit and a second phase compensation network, wherein
two output ends of the second power division circuit are respectively coupled to an input end of the first power division circuit and an input end of the second phase compensation network, and
an output end of the second phase compensation network is coupled to the input end of the third amplification branch.

15. The remote radio unit according to claim 9, wherein the first power amplifier circuit comprises any one of the following: a Doherty power amplifier, a Chireix power amplifier, a load modulated balanced amplifier (LMBA) power amplifier, or a circulator load modulated amplifier (CLMA) power amplifier.

16. The remote radio unit according to claim 9, wherein the first power amplifier circuit works first, the second power amplifier circuit works later, and the third power amplifier circuit works last.

17. A base station, comprising:
a remote radio unit; and
an antenna,
wherein the remote radio unit is coupled to the antenna, and
the remote radio unit is configured to process a transmitted or received signal of the antenna,
wherein the remote radio unit, comprising a power amplifier device, and a duplexer, wherein one end of the power amplifier device is coupled to the duplexer,
wherein the power amplifier device comprises a first power amplifier circuit, a second power amplifier circuit, a third power amplifier circuit, a first coupler, and a circulator, wherein
an input end of the first power amplifier circuit is configured to couple to a first signal, an input end of the second power amplifier circuit is configured to couple to a second signal, both an output end of the first power amplifier circuit and an output end of the second power amplifier circuit are coupled to an input port of the first coupler, and the first coupler is configured to output a signal obtained through power combination, and
an input end of the third power amplifier circuit is configured to couple to a third signal, an output port of the first coupler and an output end of the third power amplifier circuit are coupled to the circulator, and the circulator is configured to: combine power of a signal output by the third power amplifier circuit and the signal output by the first coupler, and then output a signal obtained through power combination.

18. The base station according to claim 17, wherein the second power amplifier circuit comprises a first amplification branch and a second amplification branch, and the third power amplifier circuit comprises a third amplification branch,
wherein the first amplification branch and the second amplification branch are identical, and are both biased in shallow class C, and
wherein the third amplification branch is biased in deep class C.

19. The base station according to claim 18, wherein the first power amplifier circuit is a single-transistor power amplifier, and the single-transistor power amplifier is a carrier power amplifier when biased in class AB or class B; and the power amplifier device further comprises a second coupler and a matching circuit,
wherein an input end of the carrier power amplifier is configured to input the first signal, and an output end of the carrier power amplifier is coupled to an isolation port of the first coupler,
wherein a first input port of the second coupler is configured to input the second signal, and a second input port of the second coupler is coupled to a load, two output ports of the second coupler are respectively coupled to an input end of the first amplification branch and an input end of the second amplification branch, and an output end of the first amplification branch and an output end of the second amplification branch are respectively coupled to two balanced ports of the first coupler,
wherein the output port of the first coupler is coupled to a first end of the matching circuit, and a second end of the matching circuit is coupled to an isolation port of the circulator, and
wherein an input end of the third amplification branch is configured to input the third signal, an output end of the third amplification branch is coupled to an input port of the circulator, and an output port of the circulator is configured to output a signal obtained by combining power of signals of the isolation port and the input port.

20. The base station according to claim 17, wherein the first power amplifier circuit works first, the second power amplifier circuit works later, and the third power amplifier circuit works last.
